(19) United States
(12) Patent Application Publication
(10) Pub. No.: US 2014/0015343 A1
(43) Pub. Date: Jan. 16, 2014

(54) USB MULTI-ADAPTER

(71) Applicant: Wei Chin LIN, New Taipei City (TW)

(72) Inventor: Wei Chin LIN, New Taipei City (TW)

(21) Appl. No.: 13/898,404

(22) Filed: May 20, 2013

(30) Foreign Application Priority Data
Jul. 13, 2012 (TW) 101213631

(51) Int. Cl. H03K 17/94

(52) U.S. Cl. CPC H03K 17/94
USPC 307/130

(57) ABSTRACT

A USB multi-adapter for connecting to a USB plug of an electronic device, and a USB receptacle of a laptop computer, a desktop computer, or an electric socket, includes a device identifying module including at least one USB plug and/or at least one USB receptacle, the device identifying module being capable of identifying kind of a connected electronic device based on a voltage signal in a differential pair and communicating therewith; and a mode determining module electrically connected to the device identifying module for determining whether the connected electronic device is in a power supply mode or a communication mode so that at least one electronic device can be charged by the USB multi-adapter or a communication between the at least one electronic device can be carried out by the USB multi-adapter.

### BACKGROUND OF THE INVENTION

1. Field of the Invention

The invention relates to adapters for electronic devices and more particularly to a Universal Serial Bus (USB) multi-adapter comprising a device identifying module and a mode determining module electrically connected to the device identifying module for determining whether the connected electronic device is in a power supply mode or a communication mode so as to easily and quickly supply electric power to a connected electronic device or communicate therewith.

2. Description of Related Art

Electronic products have made a great advancement in recent decades. For example, many portable electronic products have been commercially available in additional to the first generation electronic products such as desktop computers. Nowadays, improvements of electronic products are directed to increased performance, portability, multi-function, simplification, adaptability and versatility.

Conventionally, IPADs and IPODs can only be charged by their dedicated power supplies manufactured by the original manufacturers. That is, other power supplies are not possible of charging depleted IPADs or IPODs. It is required that a user carry a power supply dedicated to an electronic device being carried by himself/herself. This is a great burden to the user if there are more than one electronic device being carried. Further, it is very inconvenient.

Thus, the need for providing a universal adapter capable of charging one of a great variety of portable electronic devices exists.

### SUMMARY OF THE INVENTION

It is therefore one object of the invention to provide a USB multi-adapter for connecting to a USB plug of an electronic device, and a USB receptacle of a laptop computer, a desktop computer, or an electric socket, comprising a device identifying module including at least one USB plug and/or at least one USB receptacle, the device identifying module being capable of identifying kind of a connected electronic device based on a voltage signal in a differential pair and communicating therewith; and a mode determining module electrically connected to the device identifying module for determining whether the connected electronic device is in a power supply mode or a communication mode so that at least one electronic device can be charged by the USB multi-adapter or a communication between the at least one electronic device can be carried out by the USB multi-adapter; wherein the USB multi-adapter can connect to one of a variety of USB adapters and is applicable to one of different electronic devices; wherein the USB multi-adapter invention can connect to a power supply so that electric power can be supplied from the power supply to the USB multi-adapter; and wherein the USB multi-adapter can connect to an electronic device for data communication.

In one aspect of the invention, the USB multi-adapter can connect to one of a variety of USB adapters and is applicable to one of different smartphones, tablet computers, electronic on-board recorders, and Global Positioning Systems (GPSs). The invention can connect to a power supply so that electric power can be supplied from the power supply to the USB multi-adapter. Alternatively, the invention can connect to an electronic device for data communication. Therefore, an easy, quick, and simple charging and data communication can be carried out by the invention.

By utilizing the USB multi-adapter of the invention, in addition to dedicated power supplies, IPADs or IPODs can be alternatively charged by the USB multi-adapter and therefore a user of IPAD or IPOD has more options of power supply.

The above and other objects, features and advantages of the invention will become apparent from the following detailed description taken with the accompanying drawings.

### BRIEF DESCRIPTION OF THE DRAWINGS

FIG. 1 schematically depicts a block circuit diagram of a USB multi-adapter according to the invention.

### DETAILED DESCRIPTION OF THE INVENTION

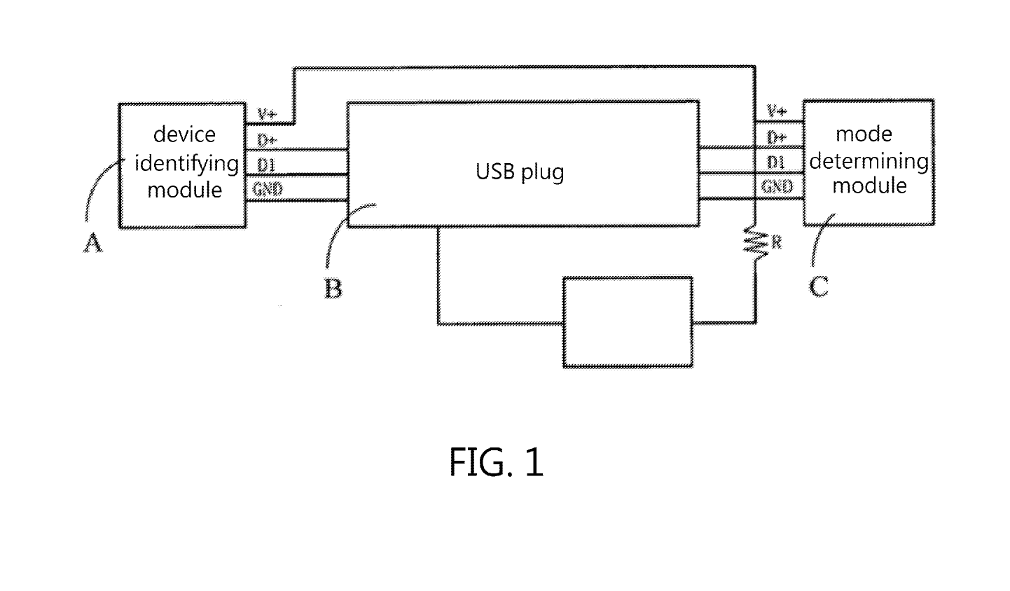

Referring to FIG. 1, a USB multi-adapter in accordance with the invention is used to connect to a USB plug of an electronic device, and a USB receptacle of a laptop computer, a desktop computer, or an electric socket. The USB multi-adapter comprises the following components as discussed in detail below.

A device identifying module A includes at least one USB plug B, at least one USB receptacle, or both. The device identifying module A identifies kind of a connected electronic device based on a voltage signal in the differential pair (D+ and D−).

A mode determining module C is electrically connected to the device identifying module A for determining whether the connected electronic device is in a power supply mode or a communication mode. Thus, at least one electronic device can be charged by the invention or a communication between a computer and at least one electronic device can be carried out by the invention.

Therefore, the invention can connect to one of a variety of USB adapters and is applicable to one of different smartphones, tablet computers, electronic on-board recorders, and Global Positioning Systems (GPSs). The invention can be connected to a power supply so that electric power can be supplied from the power supply to the USB multi-adapter. Alternatively, the invention can be connected to an electronic device for data communication. It is envisaged by the invention that an easy, quick, and simple charging and data communication can be carried out.

The USB multi-adapter of the invention further comprises a control module for allowing a user to switch between the power supply mode and the communication mode. The control module can carry out a touch control, an audio control, a switch control, a button control, or a combination thereof. The control module comprises a touch screen.

The USB multi-adapter of the invention further comprises a storage unit for storing data from a connected electronic device.

The USB multi-adapter of the invention further comprises an internal storage device (e.g., flash memory) or is adapted to connect to an external storage device (e.g., flash memory).

Each of at least one USB plug B, at least one USB receptacle, or both of the USB multi-adapter of the invention is releasable, foldable, extendable, retractable, integrally formed, or a combination thereof.

The USB multi-adapter of the invention is applicable to, but not limited to, one of a variety of electronic devices such as smartphones, tablet computers, electronic on-board recorders, and Global Positioning Systems (GPSs).

While the invention has been described in terms of preferred embodiments, those skilled in the art will recognize that the invention can be practiced with modifications within the spirit and scope of the appended claims.

What is claimed is:

1. A USB multi-adapter for connecting to a USB plug of an electronic device, and a USB receptacle of a laptop computer, a desktop computer, or an electric socket, comprising:
a device identifying module including at least one USB plug and/or at least one USB receptacle, the device identifying module being capable of identifying kind of a connected electronic device based on a voltage signal in a differential pair and communicating therewith; and
a mode determining module electrically connected to the device identifying module for determining whether the connected electronic device is in a power supply mode or a communication mode so that at least one electronic device can be charged by the USB multi-adapter or a communication between the at least one electronic device can be carried out by the USB multi-adapter;
wherein the USB multi-adapter can connect to one of a variety of USB adapters and is applicable to one of different electronic devices;
wherein the USB multi-adapter invention can connect to a power supply so that electric power can be supplied from the power supply to the USB multi-adapter; and
wherein the USB multi-adapter can connect to an electronic device for data communication.

2. The USB multi-adapter of claim 1, further comprising a control module for allowing a switching between the power supply mode and the communication mode.

3. The USB multi-adapter of claim 2, wherein a control carried out by the control module is a touch control, an audio control, a switch control, a button control, or a combination thereof.

4. The USB multi-adapter of claim 2, wherein the control module comprises a touch screen.

5. The USB multi-adapter of claim 1, further comprising a storage unit for storing data from the connected electronic device.

6. The USB multi-adapter of claim 2, further comprising a storage unit for storing data from the connected electronic device.

7. The USB multi-adapter of claim 3, further comprising a storage unit for storing data from the connected electronic device.

8. The USB multi-adapter of claim 4, further comprising a storage unit for storing data from the connected electronic device.

9. The USB multi-adapter of claim 1, further comprising an internal storage device or wherein the USB multi-adapter is adapted to connect to an external storage device.

10. The USB multi-adapter of claim 2, further comprising an internal storage device or wherein the USB multi-adapter is adapted to connect to an external storage device.

11. The USB multi-adapter of claim 3, further comprising an internal storage device or wherein the USB multi-adapter is adapted to connect to an external storage device.

12. The USB multi-adapter of claim 4, further comprising an internal storage device or wherein the USB multi-adapter is adapted to connect to an external storage device.

13. The USB multi-adapter of claim 1, wherein each of the at least one USB plug and/or the at least one USB receptacle is releasable, foldable, extendable, retractable, integrally formed, or a combination thereof.

14. The USB multi-adapter of claim 2, wherein each of the at least one USB plug and/or the at least one USB receptacle is releasable, foldable, extendable, retractable, integrally formed, or a combination thereof.

15. The USB multi-adapter of claim 3, wherein each of the at least one USB plug and/or the at least one USB receptacle is releasable, foldable, extendable, retractable, integrally formed, or a combination thereof.

16. The USB multi-adapter of claim 4, wherein each of the at least one USB plug and/or the at least one USB receptacle is releasable, foldable, extendable, retractable, integrally formed, or a combination thereof.
